(19) United States
(12) Patent Application Publication
(10) Pub. No.: US 2026/0302721 A1
(43) Pub. Date: Oct. 1, 2026

(54) LASER PACKAGE AND METHOD FOR PRODUCING SAME

(71) Applicant: ams-OSRAM International GmbH, Regensburg (DE)

(72) Inventor: Tobias HAUPELTSHOFER, Breitenbrunn (DE)

(73) Assignee: ams-OSRAM International GmbH, Regensburg (DE)

(21) Appl. No.: 19/489,859

(22) PCT Filed: Jun. 6, 2024
(86) PCT No.: PCT/EP2024/065647

§ 371 Date: Dec. 3, 2025

(30) Foreign Application Priority Data
Jun. 6, 2023 (DE) 10 2023 114 794.3

(51) Int. Cl. H01S 5/02325; H01S 5/02345; H01S 5/40

(52) U.S. Cl. CPC H01S 5/02325; H01S 5/4043; H01S 5/02345

(57) ABSTRACT

The invention relates to a laser package with a base plate and three laser elements implemented in semiconductor bodies. A transparent housing encloses the laser elements on the base plate. The laser elements have an emission area that is arranged off-center with respect to their respective semiconductor bodies and are aligned with each other in such a way that the distance between the emission areas is as small as possible. According to the invention, this is achieved, among other things, by stacking at least two of the laser elements on top of each other, with a thin interposer arranged between them.

### CROSS-REFERENCE TO RELATED APPLICATIONS

This application is a national stage entry from International Application No. PCT/EP2024/065647, filed on Jun. 6, 2024, published as International Publication No. WO 2024/251899 A1 on Dec. 12, 2024, and claims the priority of German patent application DE 10 2023 114 794.3 dated Jun. 6, 2023, the disclosures of all of which are hereby incorporated by reference in their entireties.

### FIELD

The present invention relates to a laser package and a method for manufacturing a compact laser package.

### BACKGROUND

Laser packages have a wide range of possible applications, with a particular focus on the increasing miniaturization of individual packages. One possible application is in the field of augmented reality, where lasers of different colors, for example in the red, green, and blue range, are combined with each other in order to project one or more pixels onto a display, for example augmented reality glasses or a headset. Alternatively, the pixel can also be projected directly onto the viewer's retina.

The use of different colored lasers has the advantage that they can be operated at a high power density and thus with high brightness. Different lasers can be placed together on a suitable substrate so that the laser beams can then be directed onto the display or toward the eye using one or more optical elements. For applications with very small dimensions, such as the glasses mentioned above, the emitters of the individual lasers should be brought as close together as possible to enable the use of a common optical system for the individual lasers. Piezoelectric elements can be used to guide the optics over the display or the eye in order to display different colored pixels.

Previous solutions have involved different approaches, such as the implementation of different colored lasers, each with a suitable upstream optical system that superimposes the respective laser beams. Alternatively, different colored lasers can be used, which project the respective laser light onto the display or the eye via separately controllable optics. However, this increases the space required, as well as the costs and the probability of failure, for example, due to the use of multiple piezoelectric mirrors.

In other conventional techniques, individual laser elements are stacked on top of each other to generate light for a single pixel. However, the alignment and arrangement of the individual laser elements is a problem, resulting in additional difficulties, especially in terms of beam behavior, particularly for specific areas of application.

There is therefore a need to implement a very compact laser package with multiple lasers whose combined radiation behavior is within a narrowly limited range, so that a large number of small pixels can be generated by downstream optics.

### SUMMARY OF THE INVENTION

In this context, the inventor proposes not only arranging individual laser elements next to each other on a common carrier, but also stacking several laser elements or their semiconductor bodies on top of each other, separated from each other by a very thin interposer. This thin interposer, measuring less than 10 μm, allows electrical insulation between the individual laser elements or their semiconductor bodies, whereby an additional electrical rewiring layer can be added to the interposer if required.

In contrast to conventional techniques, in which the individual laser elements are placed directly on top of each other using an interconnect material, the use of an interposer allows stacking with existing solder material based, for example, on gold and tin. This allows sufficient quality even at low temperatures and when using an interposer, in contrast to conventional techniques, where the solder material is already heavily stressed due to the increased temperature during the manufacture of the laser elements. Accordingly, an interposer can be used to achieve sufficient quality and thus a sufficiently mechanically stable attachment of various laser chips arranged on top of each other. In addition, an extra dimension is created in production, as the individual laser elements can be placed separately and only brought together in a further step. This allows, for example, the individual elements to be tested before the final production step.

The interposer itself is thin enough to bring the emission areas of the laser elements in the respective semiconductor bodies as close together as possible. This creates a very small emission area in which the partial emission areas of the individual lasers largely overlap. This significantly simplifies downstream optics.

In this context, the term “adjacent radiation areas of laser elements” refers to radiation areas whose distances are as small as possible due to the geometric alignment of the respective semiconductor bodies. In other words, the semiconductor bodies of the lasers are geometrically aligned with each other in such a way that their respective radiation areas overlap as extensively as possible, creating a common and at the same time compact radiation area for the entire package. This is achieved in particular by a decentralized arrangement of the radiation areas in the semiconductor bodies forming the respective laser element. The geometric arrangement of the semiconductor bodies relative to each other is therefore such that the respective radiation areas are as close together as possible.

Among other things, the inventor proposes a laser package with a base plate and three laser elements implemented in semiconductor bodies with different central wavelengths. A transparent housing encloses the laser elements on the base plate. The laser elements have an emission area that is arranged off-center with respect to their respective semiconductor bodies and are aligned with each other in such a way that the distance between the emission areas is as small as possib. According to the invention, this is achieved, among other things, by stacking at least two of the laser elements on top of each other, with a thin interposer arranged between them.

In one aspect of the principle underlying this application, a laser package is proposed which comprises a base plate with a housing. Together with the base plate, this forms a hermetically sealed cavity, whereby the housing is designed to be transparent to laser light at least at one point. For example, the housing may comprise glass or a similar material, which is connected to a specially designated connection area on the base plate to form a sealed cavity. This connection may be, for example, a hermetic metallic solder, but also a glass-semiconductor connection or a glass-metal connection. A hermetic seal of the cavity is useful in order to prevent possible oxidation or the formation of carbon on the emitting surfaces of individual laser elements.

According to the proposed principle, the base plate comprises at least one fastening area and at least three separate contact surfaces in the area of the cavity. A first laser element arranged in a semiconductor body with a first radiation area is now mechanically connected to a first of the at least one fastening area. The laser element is designed to generate laser light of a first central wavelength. In addition, there is a second laser element arranged in a semiconductor body with a further radiation area for generating laser light of a second central wavelength. A third laser element arranged in a semiconductor body with a third radiation area for generating laser light of a third central wavelength is also present within the cavity. The first, second, and third central wavelengths are different central wavelengths, for example in the red, green, and blue regions of the spectrum.

According to the proposed principle, the laser package further comprises an interposer which is mechanically connected to the semiconductor body of the third laser element and to at least one of the semiconductor bodies of the first and second laser elements. This connection is designed in such a way that the semiconductor body of the third laser element is arranged on the semiconductor body of the first laser element, with the interposer located between the first and second laser elements. Furthermore, at least two of the at least three contact surfaces electrically contact the first and second laser elements; a third of the at least three contact surfaces contacts the third laser element via a contact surface on the interposer.

According to the proposed principle, the emission areas of the laser elements are arranged decentrally with respect to their respective semiconductor bodies. In other words, the emission areas of the laser elements are not arranged centrally with respect to the semiconductor body, for example around an axis of rotation, but decentrally, i.e., shifted toward an edge or a corner. The corresponding semiconductor bodies are now arranged relative to each other in such a way that the emission areas are placed adjacent to each other. This results in a common emission area for the laser elements, which is defined by the emission areas of the individual elements and is as small as possible due to the adjacent arrangement relative to each other.

According to the proposed design, the emission and radiation areas of the individual laser elements are thus arranged as close to each other as possible. At the same time, sufficient image quality is achieved on both sides of the interposer and electrical insulation of the individual laser elements from each other is possible. The interposer can also be sufficiently thin to ensure adequate heat conduction through the various semiconductor bodies. This creates a thermal path that allows the individual semiconductor bodies and laser elements to be sufficiently cooled via the base plate.

In one aspect, the base plate comprises a further fastening area in the region of the cavity, to which the semiconductor body of the second laser element is mechanically connected. In this case, the third semiconductor body is thus arranged above the first semiconductor body and, if applicable, the second semiconductor body. In another aspect, an upper side of the semiconductor body of the first laser element comprises a further fastening area to which the semiconductor body of the second laser element is mechanically connected. In this configuration, the second and third laser elements are thus located on the upper side of the semiconductor body for the first laser element. In another aspect, the interposer may also be mechanically connected to the semiconductor body of the second laser element, so that the semiconductor body of the second laser element is arranged adjacent to the semiconductor body of the third laser element.

In such an embodiment, the second and third laser elements are thus arranged on the interposer and thus on the first laser element. Alternatively or additionally, the semiconductor body of the second laser element may also be arranged at least partially above the semiconductor body of the first laser element. In a further embodiment, the heights of the first and second laser elements may be equal, so that the interposer with the semiconductor body of the third laser element extends over both the top of the first laser element and the top of the second laser element.

Some aspects deal with the arrangement of the emission areas of the respective laser elements in relation to the semiconductor bodies. In some aspects, the emission areas are arranged in an edge or corner area of the respective semiconductor bodies. This central arrangement allows the respective emission areas to be arranged as close as possible to each other by means of appropriate geometric positioning, in order to achieve a total emission area whose dimensions are as small as possible.

In this context, in some aspects it is advantageous to arrange the radiation areas in an edge or corner area of the respective semiconductor bodies in such a way that they are as close as possible to each other when the three laser elements are subsequently aligned. In some aspects, the distance between the centers of two adjacent radiation areas can be less than 160 μm, and in particular less than 100 μm, and in particular less than 60 μm.

Other aspects deal with the interposer and its design. In some aspects, the interposer may have a mounting area on each of different main sides. In other words, the interposer thus comprises at least a first mounting area and a second mounting area arranged on an opposite main side. The mounting areas serve to mechanically connect the semiconductor bodies of the third laser element and the first laser element to the interposer. In some aspects, the interposer may have a thickness in the range of 20 μm to 70 μm and, in particular, less than 50 μm.

In this context, a mechanical connection means, among other things, a solder connection, for example with a gold-tin solder, whereby the fastening area of the interposer may comprise, for example, a vapor-deposited metal area. In some aspects, the interposer is made of a dielectric and, in particular, ceramic material. The fastening areas thus form a metallic surface. The fastening areas on the different main sides can be of the same size, but can also be of different sizes. The size of the fastening areas can correspond to an area of the semiconductor body to be arranged. In some aspects, the metallic surface also improves heat conduction between the semiconductor bodies and the interposer.

In other aspects, the fastening areas located on different main sides may partially overlap. This is useful if the respective semiconductor bodies of the first and third laser elements have different geometric dimensions. In this context, an edge area of the interposer may also extend beyond an edge area of a semiconductor body connected to it. Similarly, in some aspects, the interposer may have a rewiring layer, in particular on the side facing away from the first semiconductor body. This rewiring layer serves, for example, to electrically contact the third laser element.

Some aspects deal with the design of the emission areas of the three laser elements and the entire emission area of the laser package formed by the laser elements. In some aspects, the laser elements may each have a fast axis and a slow axis with respect to their radiation area. The fast and slow axes are of different sizes, so that the radiation characteristic is not circular but essentially elliptical. In some aspects, the axes of the three laser elements are oriented identically to each other.

For example, the slow axis and the fast axis of the respective laser elements can be aligned essentially parallel to each other or only at a small angle to each other, so that the radiation characteristic of the entire laser package also essentially comprises a fast axis and a slow axis. In this context, in some aspects, it is provided that the slow axis of the three laser elements is aligned essentially parallel to the base plate. In some aspects, a submount may additionally be provided within the cavity, on which the semiconductor body of the first laser element or, optionally, also the semiconductor body of the second laser element is arranged. The submount serves to create an additional distance between the radiation area of the individual laser elements and the base plate so that the emitted laser light is not shadowed or otherwise influenced by the base plate.

In some aspects, the shape of the emission areas of the three laser elements is similar to an ellipse. Each of these can have a short and a long semi-axis. The area of the emission regions is between 9000 μm² and 17,000 μm². By aligning the individual emission regions of the laser elements as closely as possible to each other, the resulting total emission also extends beyond this size or is slightly larger.

In some aspects, at least one of the three laser elements comprises a plurality of emission sub-areas arranged in rows and columns. These can be controlled individually, SO that the intensity of the emitted laser light can be adjusted by controlling them. The number of respective emission sub-areas may vary between the individual laser elements in order to accommodate different sensitivities of the eye or different emitted intensities of the individual laser elements. For example, with the same radiation intensity or power consumption, the number of emission areas for green laser light can generally be selected to be larger than those for red and blue laser light, since the eye is particularly sensitive to green light.

As mentioned, the individual emission sub-areas are different and can be controlled individually. Each of the emission sub-areas has a width of less than 2 μm and a height of less than 1 μm in some aspects. For emission sub-areas in the red spectrum, the height is slightly larger, in the range of approx. 1.8 μm. The individual emission sub-areas are arranged as close to each other as possible, with up to 12, 10, or even eight emission sub-areas being arranged in a row. The distance between two adjacent emission sub-areas can be less than 10 μm. In addition, in some aspects, the emission sub-areas are formed by the laser facets of edge-emitting lasers.

Some aspects deal with the base plate. Among other things, this can have a circumferential mounting area on which the housing is mounted to form the cavity. In some aspects, this mounting area comprises a metallic surface. In addition, the at least three contact surfaces can be coupled to contact surfaces on an opposite side of the base plate by means of various through-plating. This allows the laser package to be easily installed on a corresponding PCB board.

In other aspects, the base plate may also be designed with one or more integrated circuits. In such a design, the at least three contact surfaces are coupled to the integrated circuit(s). The integrated circuits may, for example, be designed as current drivers or, more generally, for controlling the individual laser elements or the individual emission sub-areas. This allows for a particularly space-saving design in which the base plate also forms an integrated circuit in a semiconductor body. In a further aspect, the mounting areas are designed as contact surfaces for supplying voltage or current to one of the laser elements. In this context, the mounting areas can also be designed as a common contact surface for connection to a reference potential for the first and/or second laser element. It is also possible to design the fastening areas as heat sinks in order to ensure efficient heat dissipation into the base plate.

Another aspect concerns a method for processing a laser package. Among other things, this involves providing a base plate with at least one first mounting area and at least three contact surfaces. A semiconductor body, which comprises a first laser element with an emission area arranged off-center relative to the semiconductor body, is now mechanically fastened to the mounting area.

An interposer with at least one semiconductor body is then provided. The semiconductor body comprises a third laser element with an emission area that is offset relative to the semiconductor body. This is also mechanically fastened to the semiconductor body of the first laser element in such a way that the emission areas of the first and third laser elements are adjacent to each other. A plurality of electrical contacts are then created between the at least three contact surfaces and the first and third laser elements. To protect the structure thus formed, a housing is placed on the base plate, which forms a closed cavity in which the various semiconductor bodies are arranged. The cavity thus encloses the semiconductor bodies and the plurality of electrical contact surfaces. Parts of the housing in the area of the radiation area of the laser elements are designed to be transparent.

This creates a very compact laser package in which the interposer serves to electrically separate the individual laser elements. At the same time, the interposer can be manufactured separately together with the third laser element, thereby reducing the overall thermal load on the solder required for mechanical fastening. Accordingly, the fastening contacts between the individual laser elements and between the laser elements and the base plate are improved.

Some aspects deal with the step of mechanically fastening one of the laser elements. In this step, a semiconductor body or a second laser element with an emission area arranged off-center relative to the semiconductor body is fastened to a further fastening area of the base plate. This is done in such a way that the emission area of the second laser element is adjacent to the emission area of the first and/or third laser element.

Alternatively, the step of mechanically fastening a laser element may also comprise mechanically fastening a semiconductor body of the second laser element to a fastening area on an upper side of the semiconductor body of the first laser element. As in the previous embodiment, the second laser element has an emission area that is arranged off-center relative to the semiconductor body, whereby this area is now brought as close as possible to the emission area of the first laser element by aligning and arranging the semiconductor body.

In a further aspect, the third laser element is first attached to the interposer and then the interposer is mechanically arranged on the semiconductor body of the first laser element and attached to it. In this context, it is also possible to attach another semiconductor body to the interposer and connect it to the latter, whereby this body comprises a second laser element with an emission area that is offset relative to the semiconductor body. The semiconductor body of the second laser element is designed to be adjacent to the semiconductor body of the third laser element in such a way that the respective emission areas are arranged as close to each other as possible. The semiconductor body of the second laser element can also be arranged at least partially above the semiconductor body of the first laser element.

In the respective embodiments, it is thus possible to mechanically arrange the semiconductor bodies for the third and second laser elements on the interposer and connect them to it, and then to place this structure on the semiconductor body with the first laser element and align it accordingly. This reduces the thermal load on the solder used, if necessary, and also allows separate production and alignment of the individual semiconductor bodies or laser elements.

As explained above, the emission areas of the laser elements are arranged in an edge or corner area of the respective semiconductor bodies. These areas are adjacent to each other so that the distance between the respective emission areas is as small as possible. In particular, the radiation area of two adjacent laser elements can be less than 160 μm and, in particular, less than 100 μm or even 60 μm.

In further aspects, the laser elements in the respective semiconductor bodies are contacted with the contact surfaces on the base plate or the interposer by means of bond wire connections. Such contacting can be carried out both before and after the individual semiconductor bodies are arranged on the interposer, provided that there is sufficient space for this. In this context, it is advisable to align the semiconductor bodies with the laser elements in such a way that their respective fast and slow axes are oriented in the same direction. This results in a total radiation area which, due to the spatial proximity of the individual laser elements, is also relatively small and, in particular, overlaps, so that color separation is hardly possible for the eye. A light spot generated in this way therefore appears white, and only slightly colored at the edges due to incomplete overlap.

This allows the generation of small pixels or a particularly space-saving design and generation of laser light on the eye in the field of augmented reality applications. In particular, the radiation areas of the three laser elements are between 9000 μm² and 17, 500 μm² in size. Ideally, the radiation areas of the three laser elements essentially overlap, whereby the different geometric alignment also allows for a slight widening of the entire radiation area due to the superimposition of the radiation areas of the three laser elements.

### BRIEF DESCRIPTION OF THE DRAWINGS

Further aspects and embodiments according to the proposed principle will become apparent in relation to the various embodiments and examples described in detail in connection with the accompanying drawings. FIG. 1 shows a first embodiment of a laser package according to some aspects of the proposed principle;

FIG. 2 shows a second embodiment of a laser package according to some aspects of the proposed principle;

FIG. 3 illustrates a side view of an embodiment of a laser element according to some aspects of the proposed principle;

FIG. 4 shows a top view of the embodiment of FIG. 3;

FIG. 5 illustrates a third embodiment of a laser package according to some aspects of the proposed principle;

FIG. 6 shows a fourth embodiment of a laser package according to some aspects of the proposed principle;

FIG. 7 shows a fifth embodiment of a laser package according to some aspects of the proposed principle;

FIGS. 8A to 8E illustrate some aspects of a method for producing a laser package according to the proposed principle;

FIG. 9 is a view of an edge-emitting laser for illustrating some aspects of the proposed principle.

### DETAILED DESCRIPTION

The following embodiments and examples illustrate various aspects and combinations thereof according to the proposed principle. The embodiments and examples are not always to scale. Likewise, various elements may be enlarged or reduced in size to highlight individual aspects. It goes without saying that the individual aspects and features of the embodiments and examples shown in the figures can be readily combined with each other without compromising the principle of the invention. Some aspects have a regular structure or shape. It should be noted that in practice, slight deviations from the ideal shape may occur without contradicting the inventive idea.

Furthermore, the individual figures, features, and aspects are not necessarily shown in their correct size, and the proportions between the individual elements do not necessarily have to be correct. Some aspects and features are emphasized by being shown enlarged. However, terms such as “above,” “above,” “below,” “below,” “larger,” “smaller,” and the like are correctly represented in relation to the elements in the figures. It is thus possible to deduce such relationships between the elements from the illustrations.

FIG. 1 shows an embodiment of a laser package according to some aspects of the proposed principle. The laser package 1 comprises a base plate 10, for example made of a dielectric ceramic material, with a number of feedthroughs. These feedthroughs connect contact surfaces 35a on the underside of the base plate 10 to corresponding contact surfaces 25, 36, and 37 on the top side of the base plate. The feedthroughs are insulated from each other, which is possible without major difficulty in a ceramic material. Alternatively, however, the base plate may also be made of a semiconductor material or another substance, in which case the feedthroughs are insulated from each other by a corresponding dielectric material.

The laser package 1 also comprises a housing 11, which is designed to be transparent with a glass material and is firmly mechanically connected to the base plate 10, creating a cavity. The contacts 35, 36, and 37 on the upper side of the base plate are located inside the cavity. The base plate 10 also comprises mounting areas 100 and 101. The mounting area 100 is designed with a metallic surface and is connected to a feedthrough for the contact 38 on the underside of the base plate 10.

Two semiconductor bodies, each containing a laser element 12 and 13, are now applied to the mounting areas 100 and 101. For the purposes of this application, for the sake of simplicity, the term “semiconductor body” is equated with the term “laser element” or “laser element implemented in the semiconductor body,” since a corresponding laser element is formed within the respective semiconductor body.

The laser element 12 comprises an emission area 16a, which is located in the upper left corner as shown. For this purpose, the laser element 12 is equipped with several edge-emitting laser structures, which are represented by small dots in the upper right corner. The emission area 16a results from an overlap of the sub-areas of the individual laser structures. Accordingly, the emission area 16a for the first laser element is thus arranged off-center with respect to a rotation axis of the semiconductor body. The semiconductor body comprises a contact on the underside and several second contact surfaces 120 on the upper side (only one shown). This is electrically connected to the contacts 37 of the base plate 10 via several bonding wires 31 (only one shown) and electrically contacts the individual edge-emitting laser structures of the laser element 12 for individual control.

A second laser element 13 is mechanically and electrically attached to the second mounting area 101 at a slight distance from the first laser element 12. This second laser element 13 also comprises an emission area 16b arranged off-center with respect to a rotational or central axis of the semiconductor body. The second laser element is constructed similarly to the first laser element, i.e., with several laser structures arranged next to each other. However, these have a different central wavelength. While the laser element 12 is designed to emit green laser light, for example, the laser element 13 generates red laser light during operation. Accordingly, the number of laser structures in elements 12 and 13 may differ.

The two laser elements 12 and 13 are arranged and aligned in such a way that the respective emission areas 16a and 16b are aligned as closely as possible to each other so that, ideally, they overlap in a large subarea. As shown in FIG. 1, this is achieved by bringing the two semiconductor bodies as close together as possible, with the radiation areas being located in the upper right corner and upper left corner, respectively. In this embodiment, the distance between the two semiconductor bodies or laser elements 12 and 13 is only a few μm. An electrical connection is also provided for the second laser element by means of bonding wires 33, which connect the contact surfaces 35 of the base plate 10 to corresponding contact surfaces on the upper side of the semiconductor body of the second laser element 13.

According to the invention, an interposer 15 is now provided, which comprises a fastening area 151 and is thus mechanically fastened to a fastening area 123 on the upper side of the semiconductor body 12. On the one hand, a further contact surface 153 is applied to the interposer 15, and on the other hand, an additional fastening area 152, to which a third laser element 14 in a semiconductor body is finally mechanically connected. This laser element 14 also comprises a decentralized emission area 16c and is constructed in the same way as the previous laser elements. As shown, the semiconductor body for the laser element 14 on the interposer 15 is geometrically aligned so that the emission area 16c overlaps as extensively as possible with the other emission areas 16a and 16b. This results in a total radiation area 16 for the laser package, which is characterized in its central area by an overlap of the respective colors. In this way, for example, a white pixel can be generated. Only in the peripheral area of this common emission area 16 for the laser package are the individual colors of the laser elements 12, 13, and 14 still visible. By controlling individual lasers, other mixed colors with different intensities can also be provided. The laser package is thus designed to generate RGB colors.

The individual semiconductor bodies are mechanically fastened to both the base plate 10 and the interposer 15 using a gold-tin solder connection. The solder has various positive properties, but is also subject to oxidation, meaning that high continuous thermal stress can lead to deterioration of the mechanical connection. For this reason, the structure shown in FIG. 1 is proposed in accordance with the invention, in which an additional interposer 15 is provided. This is designed to be as thin as possible in order to ensure a large overlap area between the individual emission areas. However, the advantage here is that during the process of aligning and fastening the laser elements, the thermal stress on the gold-tin solder used can be reduced, thereby reducing oxidation and improving stability and mechanical fastening. Accordingly, for example, the structure consisting of the second laser element 14 and the interposer 15 can be manufactured and tested separately before the fastening area 151 of the interbrowser 15 and the area 123 of the first laser element are subsequently connected to each other.

The laser package produced in this way generates a laser light which, in the present case, moves out of the drawing plane. The housing 11 is designed to be transparent at this point so that the superimposed laser light can be directed onto a display, an eye, or another projection device by means of downstream optics.

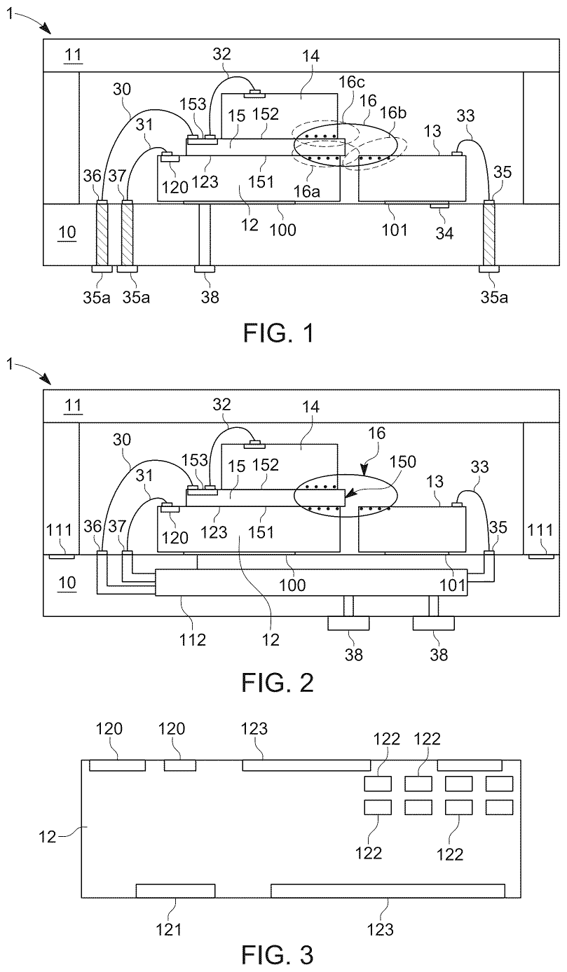

FIG. 2 shows a further embodiment of a laser package according to the proposed principle. In this embodiment, the individual laser elements and their semiconductor bodies are aligned with each other in a similar manner as in the embodiment shown in FIG. 1. Bond wires 30 to 33 connect the individual laser elements, with bond wires 30 and 32 each being connected to the rewiring layer 153 on the upper side of the interposer 15. This allows the available space to be used as efficiently as possible, thus achieving control of the individual laser elements with a low overall space requirement.

The base plate 10 is made of a semiconductor material and comprises a surrounding metallic connection area 111, on which the transparent housing 11 is placed and hermetically sealed to the base plate 10 by means of a glass-metal connection or glass-solder connection. In addition, the base plate 10 comprises an integrated circuit 112, which is connected to the individual contact surfaces 35 to 37 on the upper side of the base plate for controlling the individual laser elements. Among other things, the integrated circuit 112 serves to provide the necessary current and voltage signals to the individual laser elements. This further reduces the space required for such a laser package, since the elements necessary for control and the driver circuit are already at least partially integrated in the base plate 10 and therefore only need to be supplied with the necessary supply and control signals via contact areas 38 on the underside of the plate 10. Similar to the previous embodiment, the mounting areas 100 and 101 for the respective laser elements 12 and 13 also form contact surfaces for supplying, for example, a reference potential.

The embodiments shown in FIGS. 1 and 2 each comprise a decentralized emission area 16a, 16b, and 16c in their laser elements 12 to 14, which overlap to form a common emission area 16. For this purpose, the individual laser elements have several laser structures arranged in parallel, whose emission areas are referred to as partial emission areas. In these embodiments, the laser structures are formed by edge-emitting lasers. However, other lasers such as VCSEL or others can also be used.

FIG. 3 shows a side view of a semiconductor body with such a laser element 12. The other laser elements 13 and 14 are constructed similarly. The semiconductor body of FIG. 3 comprises, in its upper right corner shown here, several edge-emitting laser structures 122, each of which forms a partial radiation area of the laser element. The laser structures 122 can be controlled individually. For this purpose, several contact areas 120 are applied to the upper side of the semiconductor body of the laser element 12 for contacting and controlling the individual laser structures 122.

The contact areas are designed, for example, as metallized surfaces. There is also a common contact area 122 on the underside of the semiconductor body and two metallized mounting areas 123. These serve on the one hand to dissipate heat and on the other hand to mechanically attach the laser element to an interposer or the base plate. The laser structures 122 are arranged off-center relative to a central axis of rotation of the body and, in this embodiment, are located in a corner or edge area. With suitable mapping of different laser elements onto each other, an overlapping emission area can be formed in this way. In addition, the edge-emitting laser structures 122 in the semiconductor body 12 are constructed in such a way that their long axis runs essentially parallel to the top or bottom surface and their fast axis is perpendicular to it. In particular, the individual laser structures in this embodiment are designed such that their respective slow and fast axes are oriented in the same direction relative to each other. However, other orientation options are also conceivable.

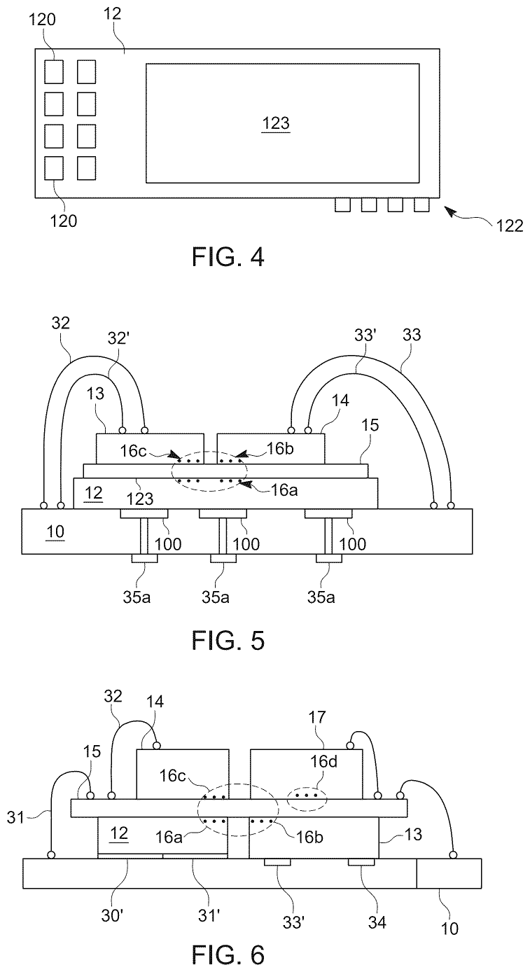

FIG. 4 shows a top view of such a semiconductor body 12 with its integrated laser structures 122. Several contact areas 120 are arranged in rows and columns on the upper side of the semiconductor body 12. These comprise a metallized surface onto which bonding wires can be applied. A further mounting surface 123 is arranged flat on the upper side and also comprises a metallized surface onto which a gold-tin alloy is applied as solder material.

The embodiments shown in FIGS. 1 and 2 are designed such that the interposer 15 is arranged between a first laser element 12 and a second element 14. The third laser element, on the other hand, is also located on the base plate 10 near the first laser element, resulting in the emission area shown in FIG. 12. However, depending on the design, other combinations and arrangements of the individual semiconductor bodies and laser elements relative to each other can also be defined without detracting from the inventive concept. This flexibility in manufacturing is particularly advantageous when the individual radiation areas of the laser elements used are also arranged decentrally but differ with respect to the respective axes of symmetry.

FIG. 5 shows a design with a corresponding arrangement. Elements with the same function or construction have the same reference symbols. In this design, the first semiconductor element 12 comprises an elongated and cuboid semiconductor body in which the individual laser structures define an emission area 16a located centrally in the upper edge area. In contrast to the previous embodiments, the laser element 12 thus does not comprise an emission area in a corner area, but only in an edge area, which may be centrally or slightly off-center.

Several contact surfaces are applied to the underside of the semiconductor body of the laser element 12, which are connected both mechanically and electrically to contact and fastening areas 100. The mounting areas 100 lead to the corresponding contact surfaces 35a on the opposite side of the base plate 10 via several through-plated connections. These thus allow individual control of the individual structures in the laser element 12. An interposer 15 is soldered onto the mounting area 123 on the upper side of the laser element 12, to which two laser elements 13 and 14 are in turn attached. Their emission areas are located at the lower right and lower left corners, respectively, resulting in an overlapping and narrowly defined overall emission area 16.

In this embodiment, the two laser elements 13 and 14 are designed so that they are controlled via corresponding contact surfaces on the upper side by means of bonding wires 32 and 33, respectively. In other words, in this embodiment, contacting is not formed in part via contact surfaces or a rewiring layer on the interposer 15, as in the previous embodiments, but directly via bonding wires that are guided to the base plate 10. Alternatively or additionally, as in the previous embodiments, at least one of the laser elements can first be connected to a rewiring layer of the interposer 15 and then from there to the contact surfaces on the upper side of the base plate 10. The housing 11 surrounding the laser package is no longer shown here for reasons of clarity.

FIG. 6 shows a further embodiment of the invention in which, in addition to the three existing laser elements with different central wavelengths, a fourth laser element 17 is mechanically and electrically attached to the interposer 15. During operation, the laser element 17 generates light of a central wavelength, in particular infrared light, and serves, for example, to characterize the movement of the eye in relation to the emission area.

For this purpose, the corresponding emission area 16d can be separated from the other emission areas 16a, 16b, and 16c and not form part of the common emission area 16. Here too, the laser element 17 is mechanically soldered to the interposer 15 via a gold-tin alloy on the one hand and, on the other hand, connected via bonding wires to contact surfaces of the interposer and from there to the base plate 10. The two laser elements 12 and 13 are connected mechanically on the one hand and electrically on the other hand to the mounting areas 30′, 31′, 33′ and 34. In this embodiment, the height of the two laser elements 12 and 13 is the same, so that the interposer 15 extends essentially flat over the surface of the two semiconductor bodies of the laser elements 12 and 13. Among other things, this leads to improved stabilization, but also to simplified manufacture of the entire package. Alternatively, two separate interposers, possibly of different widths, may be provided in this context, on which the laser element 14 with its visible light and the laser element 17 with its further emission range 16d and its infrared light are mounted.

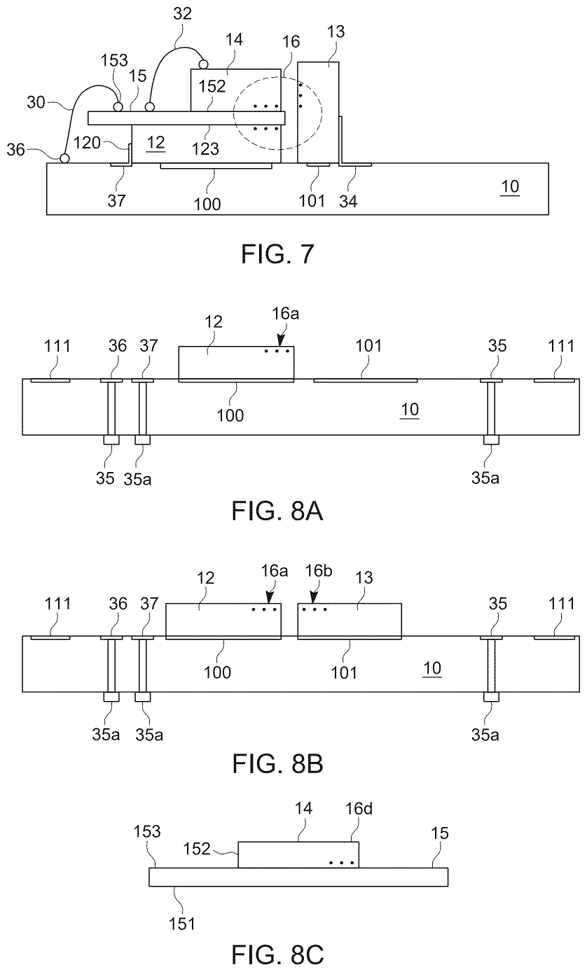

A further embodiment is shown in FIG. 7. In this embodiment, the first laser element 12 comprises a contact and mounting area on its underside, which is connected to the mounting area 100 of the base plate 10 via a gold-tin alloy. However, a further contact surface 110 is arranged on a side wall of the semiconductor body of the laser element 12 and is electrically conductively connected to a corresponding contact surface 37 via a solder drop. This allows, on the one hand, precise alignment and, on the other hand, additional possible dimensioning that does not require any further bond wire connection. In this context, the contact surface 110 can also be arranged on the underside. An interposer 15 is mechanically connected to the mounting area 123. On the interposer, a rewiring layer 153 is provided on the one hand, and on the other hand, a further mounting area 152 to which the laser element 14 is attached. Several third bonding wires 30 and 32 carry the corresponding signal and power supply to the laser element 14 from the base plate via the interposer and the rewiring layer 153.

In this embodiment, the additional third laser element 13 is now arranged vertically so that its emission areas located in the edge region can be brought as close as possible to the emission areas for the laser elements 12 and 13. A conductive material electrically connects a connection surface 34 of the base plate 10 to a corresponding contact surface on the surface opposite the emission areas of the laser element 13. The edge of the semiconductor body of the laser element 13 forms a mounting area and is mechanically connected to the area 101 of the base plate 101 via the gold-tin solder connection.

With the solution according to the invention as shown in the respective embodiments, it is thus possible, by means of a corresponding geometric arrangement, to bring the emission areas of the individual laser elements sufficiently close together to achieve a common and overlapping emission area for the different colors of the laser elements. This simplifies the downstream optics, as these no longer need to be provided for each laser light as in conventional techniques, but rather the radiation area 16 overlaps sufficiently due to the geometric arrangement and the very small distance between the individual partial emission areas to be able to display different colors, including white.

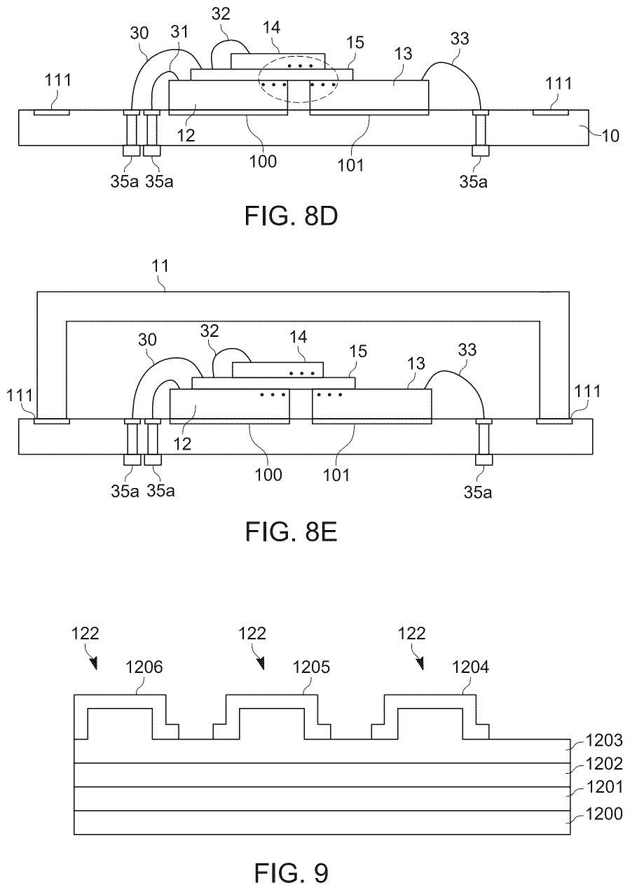

FIGS. 8A to 8E show various aspects of a method for manufacturing such a laser package according to the proposed principle. In FIG. 8A, a base plate 10 is provided, which is made, for example, of a ceramic material with a plurality of through-plated contacts. The through-plated holes are filled with a metallic or conductive material and contact contact areas 35a on the underside with corresponding contact areas 35, 36, and 37 on the opposite upper side. The base plate 10 is also designed with several fastening areas 100 and 101. In the present embodiment, these fastening areas are separated from each other. Alternatively, however, it is also possible to provide a single larger fastening area 100 and to align the individual semiconductor bodies with their laser elements directly with each other during subsequent fastening. This can simplify manufacturing and, if necessary, also heat dissipation and the supply of a common potential.

The base plate 10 also comprises a circumferential connection area 111 which extends around the fastening areas 100 and 101 and the contact surfaces 35 to 37. This connection area 111 is later used to accommodate a glass solder connection for the mechanical and hermetic sealing of the laser elements. After providing such a base plate, a semiconductor body with a first laser element 12 is placed on the fastening area 100 and soldered in place. The semiconductor body is aligned and fastened to the area 100 in such a way that the emission area 16a faces the second fastening area 101 and is turned away from the first fastening area 100.

In a subsequent second step shown in FIG. 8B, a second semiconductor body with a second semiconductor element 13 is applied to the mounting area 101, aligned, and then mechanically fastened using gold-tin solder. The alignment and attachment are carried out in such a way that a small gap of a few micrometers remains between the two semiconductor bodies, but they are brought as close as possible to each other. In this design, the second laser element 13 is now configured so that its radiation area 16b is brought as close as possible to the radiation area 16a of the first laser element, so that they overlap to a large extent.

Parallel to the production of this section, an interposer 15 is provided, which has a first larger fastening area 151 on its underside and a second fastening area 152 on its upper side. The interposer 15 is only a few micrometers thick and comprises a ceramic dielectric material. In addition, a rewiring layer 153 with a plurality of contact surfaces is provided on its upper side next to the fastening area 152. Similar to the process control of the base plate 10, a semiconductor body with a further laser element 14 is now applied to the fastening area 152 and fastened to it using solder. The semiconductor body is aligned in such a way that the emission area 16d is arranged adjacent to the surface of the interposer 15. This approach of arranging the laser elements separately from each other on the interposer 15 and the base plate 10 reduces the thermal load, in particular on the solder material used, thereby reducing oxidation and thus improving the mechanical connection.

In a further step shown in FIG. 8D, the two elements are now combined with each other and the interposer 15 is placed on top of the semiconductor bodies of the laser elements 12 and 13 and aligned. The alignment is carried out in such a way that the emission areas of the individual laser elements 12, 13, and 14 overlap as extensively as possible, resulting in a uniform but small common emission area 16. After alignment, the interposer 15 can be soldered to the semiconductor bodies for the laser elements 12 and 13 via the mounting areas. This is followed by a connection in which the individual contact surfaces on the interposer or the upper sides of the semiconductor bodies are electrically connected to the contact surfaces on the base plate 10. These individual steps allow extensive testing of the individual components during the manufacturing process in order to identify errors or damage at an early stage and, if necessary, replace individual components without having to discard the entire package.

After a functional test, the transparent housing 11 is then placed on top and attached to the connection surfaces 111 using a glass slot or a glass-metal connection. This seals the individual laser elements 12, 13, and 14 off from the environment and hermetically seals them. This last step can also be carried out in a sphere to prevent possible contamination of the laser facets, for example by carbon, during subsequent operation.

Finally, FIG. 9 shows the design of a semiconductor laser with several edge-emitting laser structures, each of which represents emission sub-areas. Such a structure is provided, among other things, in the laser elements 12, 13, and 14, whereby the individual edge-emitting laser structures can be individually controlled by means of corresponding contacts. The laser element in FIG. 9 comprises a semiconductor substrate 112 with several differently doped layers 1200 to 1203. These are partly p-and n-doped, whereby both the doping concentration and the doping gradient can vary. Further measures such as charge carrier blocking layers and other structures may also be provided. Layer 1202 also comprises a multiple quantum well, which acts as a light-generating layer for the generation of light of a central wavelength. Depending on the material system used, light of different wavelengths can be generated in this way.

The top layer 1203 is now additionally structured to form several adjacent and longitudinally oriented ridges, also referred to as “ridges.” These are each covered with a conductive material 1204, 1205, and 1206, for example, a metal. The metals of layers 1204 are electrically isolated from each other, and the ridges shown in FIG. 9 constrain the light generation in the multiple quantum well to these areas, with the generated light oscillating perpendicular to them and emerging at an edge (e.g., out of the drawing plane).

When the arrangement is in operation, the individual metallic layers 1204 to 1206 can be controlled to excite the respective patches for generating laser light in the multiple quantum world structure 1.2.2002.

The proposed principle allows very small laser packages to be realized, which are particularly suitable for augmented reality applications. The flexibility in generating different colors by using laser elements with different central wavelengths and different intensities is retained, as the respective laser elements have several laser structures, which in turn can be controlled individually. The interposer used is very thin, measuring just a few micrometers, in order to ensure sufficient overlap of the different emission areas of the individual laser elements. The designs primarily referred to a gold-tin alloy as the material for mechanical fastening. Of course, a different solder connection can be used instead of such a material.

1. A laser package comprising:
a base plate with a housing which, together with the housing forms a cavity, in particular a hermetically sealed cavity, which is designed to be transparent to laser light at least at one point,
wherein the base plate comprises at least one mounting area and at least three contact surfaces in the area of the cavity;
a first laser element arranged in a semiconductor body with a first emission area which is mechanically connected to a first of the at least one fastening area and is designed to generate laser light of a first central wavelength;
a second laser element arranged in a semiconductor body with a second emission region for generating laser light of a second central wavelength;
a third laser element arranged in a semiconductor body with a third radiation area for generating laser light of a third central wavelength;
an interposer which is mechanically connected to the semiconductor body of the third laser element and to at least one of the semiconductor bodies of the first and second laser elements so that the semiconductor body of the third laser element is arranged on the semiconductor body of the first laser element wherein
two of the at least three contact surfaces electrically con-tact the first and second laser elements, and a third of the at least three contact surfaces contacts the third laser element via a contact surface on the interposer; and wherein
the emission areas of the laser elements are arranged off-center relative to their respective semiconductor bodies and adjacent to each other.

2. The laser package according to claim 1, wherein
the base plate comprises a further fastening area in the region of the cavity, to which the semiconductor body of the second laser element is mechanically connected; or
in which an upper side of the semiconductor body of the first laser element comprises a further fastening area to which the semiconductor body of the second laser element is mechanically connected; or
wherein the interposer is mechanically connected to the semiconductor body of the second laser element such that the semiconductor body of the second laser element is adjacent to the semiconductor body of the third laser element and/or the semiconductor body of the second laser element is at least partially arranged above the semiconductor body of the first laser element.

3. The laser package according to claim 1, wherein
the emission areas are arranged in an edge or corner area of the respective semiconductor bodies, wherein these edge or corner areas of the respective semiconductor bodies are adjacent to each other; or
the emission areas are arranged in an edge or corner area of the respective semiconductor bodies, wherein these edge or corner areas are at the smallest possible distance from each other; and/or
wherein a distance between centers of two adjacent radiation areas is less than 160 μm, less than 100 μm or, less than 60 μm.

4. The laser package according to claim 1, wherein
the interposer comprises a fastening area on each of its different main sides, to which the semiconductor body of the third laser element and the semiconductor body of the first laser element are mechanically connected; and/or
the interposer comprises a thickness in a range of 20 μm to 70 μm, or less than 50 μm.

5. The laser package according to claim 4, wherein
the interposer comprises a dielectric, in particular ceramic, material and the fastening areas have a metallic surface; and/or
the fastening areas located on different main sides are of different sizes; and/or
the fastening areas located on different main sides only partially overlap; and/or
the contact surface of the interposer is arranged on the main side with the fastening area for the semiconductor body of the third laser element; and/or
at least one edge area of the interposer protrudes beyond an edge area of a semiconductor body connected to it; and/or
the interposer comprises a rewiring layer, in particular on its side facing away from the first semiconductor body, which electrically contacts the contact surface of the interposer.

6. The laser package according to claim 1, wherein
the laser elements each comprise a fast axis and a slow axis, wherein the axes of the three laser elements are each oriented identically to one another; and/or
the laser elements each comprise a fast axis and a slow axis, wherein the slow axis of the three laser elements is aligned substantially parallel to the base plate and/or
the radiation areas of the three laser elements lie in a common area having a size between 9000 μm² and 17500 μm².

7. The laser package according to claim 1, in which at least one of the three laser elements comprises a plurality of emission sub-areas arranged in rows and columns, which can be controlled individually, each of the emission sub-areas optionally having a width of less than 2 μm and a height of less than 1 μm or less than 1.8 μm.

8. The laser package according to claim 7, wherein the emission sub-areas are formed by edge-emitting lasers.

9. The laser package according to claim 1, wherein
the at least three contact surfaces are coupled by through-plating to contact surfaces on an opposite side of the base plate; and/or
the at least three contact surfaces are coupled to an integrated circuit present in the base plate.

10. The laser package according to claim 1, wherein at least one of the fastening areas is designed as a contact surface for supplying voltage or current to one of the laser elements.

11. The laser package according to claim 1, wherein the fastening areas for mechanically fastening the semiconductor bodies comprise solder.

12. A method for processing a laser package, comprising:
providing a base plate with at least one fastening area and at least three contact surfaces;
mechanically fastening a semiconductor body, which comprises a first laser element with an emission area arranged off-center relative to the semiconductor body, on the fastening area;
mechanically fastening an interposer with at least one semi-conductor body, which comprises a third laser element with an emission area arranged off-center relative to the semiconductor body, to the semiconductor body of the first laser element in such a way that the emission areas are adjacent to each other;
establishing electrical contacts between the at least three contact surfaces and the first and third laser elements; and
placing a housing on the base plate to form a cavity, in particular a hermetically sealed cavity, wherein the housing is designed to be transparent to laser light in the region of the emission areas.

13. The method according to claim 12, wherein mechanically fastening an interposer comprises:
mechanically fastening a semiconductor body, which comprises a second laser element with an emission area arranged off-center relative to the semiconductor body, on a further fastening area in such a way that the emission area of the second laser element is adjacent to the emission areas of the first and third laser elements; and/or
mechanically fastening a semiconductor body, which comprises a second laser element with an emission area arranged off-center relative to the semiconductor body, to a fastening area on an upper side of the semiconductor body of the first laser element; and/or
mechanically fastening a semiconductor body, which comprises a second laser element with an emission area arranged off-center relative to the semiconductor body, to a further fastening area of the interposer, so that the semiconductor body of the second laser element is adjacent to the semiconductor body of the third laser element and/or the semiconductor body of the second laser element is arranged at least partially above the semiconductor body of the first laser element.

14. The method according to claim 12, in which mechanical fastening is carried out by soldering on metallized fastening areas.

15. The method according to claim 12, wherein
the emission areas are arranged in an edge or corner area of the respective semiconductor bodies, wherein these edge or corner areas of the respective semiconductor bodies are adjacent to each other; or
the radiation areas are arranged in an edge or corner area of the respective semiconductor bodies, wherein these edge or corner areas are at the smallest possible distance from each other; and/or
in which a distance between centers of two adjacent radiation areas is less than 160 μm and, in particular, less than 100 μm and, in particular, less than 60 μm.

16. The method according to claim 12, wherein
the interposer comprises a fastening area on each of its different main sides, with which the semiconductor body of the third laser element and the semiconductor body of the first laser element are mechanically connected.

17. The method according to claim 12, wherein
the interposer comprises a dielectric, in particular ceramic, material and the fastening areas have a metallic surface; and/or
the fastening areas located on different main sides are of different sizes; and/or
the fastening areas located on different main sides only partially overlap; and/or
the contact surface of the interposer is arranged on the main side with the fastening area for the semiconductor body of the third laser element; and/or
at least one edge area of the interposer protrudes beyond an edge area of a semiconductor body connected to it; and/or
the interposer comprises a rewiring layer, in particular on its side facing away from the first semiconductor body, which electrically contacts the contact surface of the interposer.

18. The method according to claim 12, wherein
the laser elements each have a fast axis and a slow axis, wherein the axes of the three laser elements are each oriented identically to one another; and/or
the laser elements each have a fast axis and a slow axis, wherein the slow axis of the three laser elements is aligned substantially parallel to the base plate.

19. The laser package according to claim 11, wherein the solder is AuSn.

20. The method according to claim 14, wherein mechanical fastening carried out by soldering on metallized fastening areas comprises soldering with a gold-tin alloy.
